(19) United States
(12) Patent Application Publication
(10) Pub. No.: US 2020/0097105 A1
(43) Pub. Date: Mar. 26, 2020

(54) ALLOY FOR MAKING TRACE WIRES AND TOUCH PANEL USING THE SAME

(71) Applicant: FLEX TEK CO., LTD., Taoyuan City (TW)

(72) Inventors: TSUNG-HER YEH, Taoyuan City (TW); KUO-CHEN HSU, Hsinchu County (TW); SHINN-GUANG CHUNG, Taoyuan City (TW)

(21) Appl. No.: 16/292,617

(22) Filed: Mar. 5, 2019

(30) Foreign Application Priority Data
Sep. 21, 2018 (TW) 107133443

(51) Int. Cl. G06F 3/041; H05K 1/02; H05K 1/09; B22F 1/02; B32B 15/01; B32B 15/20

(52) U.S. Cl. CPC G06F 3/041; H05K 1/0274; H05K 1/092; B22F 1/025; B32B 15/018; B32B 15/20; B22F 2304/05; H05K 2201/10128; H05K 2201/10151; H05K 2201/0108; H05K 2201/026; B22F 2301/255; B22F 2301/10; G06F 2203/04107

(57) ABSTRACT

Disclosures of the present invention mainly describe an alloy for making trace wires of a touch panel. The alloy consists of a first clapping layer, a copper layer, and a second clapping layer. By applying the alloy as the trace wires of the touch panel, feather-like microstructures are effectively prevented from forming between the trace wires and sensor units of the touch panel. On the other hand, because the alloy is able to completely defense the corrosion attack coming from HNO₃-based etchant, the trace wires made of the alloy exhibits an outstanding corrosion resistant during the patterning process of the AgNW-made sensor units. Therefore, during patterning the AgNW-made sensor units, the trace wires can have a large processing window, such that the touch panel is hence able to have a good manufacturing yield rate and possesses an outstanding reliability.

### BACKGROUND OF THE INVENTION

### 1. Field of the Invention

The present invention relates to the technology field of touch panels, and more particularly to an alloy for making trace wires and touch panel using the same.

### 2. Description of the Prior Art

Nowadays, touch panel module comprising transparent conductive substrate, driving circuit and sensing circuit has been widely applied in the electronic device having small size display screen, such as smart phone and tablet PC. However, with the growing of demands made by market on All-in-One PCs, large-size laptop PCs and large-size touch displays, expensive manufacturing cost and high sheet resistance of traditional ITO transparent conductive substrate have become the major problems of large-size touch panels. Engineers skilled in development and manufacture of the transparent conductive substrate should know that, the cost of forming ITO electrode layer occupies around 40% of a total manufacturing cost of the traditional ITO transparent conductive substrate. Moreover, ITO electrode layer formed on a glass substrate of the ITO transparent conductive substrate commonly exhibits an average sheet resistance of 100-150 ohm/sq.

ITO touch panels are classified to two types including single-sided ITO touch panel and double-sided ITO touch panel. FIG. 1 and FIG. 2 respectively show a top view diagram and a cross-sectional side view of the conventional double-sided ITO touch panel. From FIG. 1 and FIG. 2, it is understood that the double-sided ITO touch panel 1′ mainly comprises: a transparent substrate 10′, a plurality of first sensor units 11′ formed on top surface of the transparent substrate 10′, a plurality of second sensor units 12′ formed on bottom surface of the transparent substrate 10′, a plurality of first extension wires 13′, and a plurality of second extension wires 14′. Particularly, dotted rectangular frame has marked that the first sensor units 11′ and the second sensor units 12′ are arranged in a visible region VR′ of the touch panel 1′. On the other hand, there is a non-visible region IVR′ defined between the dotted rectangular frame and a solid rectangular frame as shown in FIG. 1, and the first extension wires 13′ and the second extension wires 14′ are arranged in the non-visible region IVR′.

The first extension wires 13′ and the second extension wires 14′, commonly made of silver (Ag) or copper (Cu), constitute trace wires on the transparent substrate 10′. It is worth explaining that, increasing of the manufacturing cost resulted from year to year decreasing of the indium resources has become the most important problem for the ITO transparent conductive substrate. Thus, for the purpose of manufacturing cost saving, manufacturers of the transparent conductive substrate have made great efforts to research and develop a new material of silver nanowire (AgNW) for replacing ITO so as to be used in the manufacture of the sensor units 11′ and 12′. The AgNW-made sensor units 11′ and 12′ exhibit an average sheet resistance of 30-50 ohm/sq.

FIG. 3A and FIG. 3B show diagrams for describing manufacturing process flow of the first sensor units and the first extension wires. The process flow firstly executes step S1′, so as to sequentially form an AgNW layer SNW′ and a copper layer CL′ on top surface of a transparent substrate 10′. After that, in steps S2′ and S3′, a patterned first photoresist layer PR1′ is formed on the copper layer CL′, and then a first etching process is utilized for removing at least one specific portion of the AgNW layer SNW′ and the copper layer CL′ uncovered by the first photoresist layer PR1′. It is worth noting that, a plurality of first sensor units 11′ are formed on the transparent substrate 10′ after the first etching process is finished. Furthermore, in steps S4′ and S5′, a patterned photoresist layer PR2′ is formed on the copper layer CL′ and the first sensor units 11′, and then a second etching process is utilized for removing at least one specific portion of the copper layer CL′ uncovered by the second photoresist layer PR2′. It is worth noting that, a plurality of first extension wires 13′ are formed on the transparent substrate 10′ after the second etching process is completed, so as to respectively connected to the plurality of first sensor units 11′. It is easily extrapolated that, a plurality of second sensor units 23′ and a plurality of second extension wires 14′ can also be formed on bottom surface of the transparent substrate 10′ by using the manufacturing steps S1′-S5′.

After finishing the step S5′, a touch panel having MOS structure is obtained. Herein, MOS is an abbreviation of “Metal-On-Silver nanowires”. It needs to particularly explain that, during the execution of the first etching process, a first etchant comprising principle etching ingredient of HNO₃ or FeCl₃ is firstly applied to the copper layer CL′, and therefore a second etchant comprising principle etching ingredient of HNO₃ is subsequently applied to the AgNW layer SNW′. However, inventors of the present invention find that, Galvanic displacement reaction and nucleation reaction would occur between AgNO₃ and Cu element of the copper layer CL′, wherein the AgNO₃ is produced during using HNO₃ to etch the AgNW layer SNW′. Consequently, Galvanic displacement reaction and nucleation reaction cause that feather-like microstructures are formed between the copper layer CL′ and the first sensor units 11′. Chemical reaction equations for the feather-like microstructures are presented as follows.

3Ag+4HNO₃(aq)→AgNO₃(aq)+2H₂O(I)+NO(g) (1)

Cu+2AgNO₃(aq)→Cu(NO₃)₂(aq)+2Ag (2)

From the two chemical reaction equations, it is understood that the feather-like microstructures should comprise Ag contributed by AgNO₃, Cu contributed by copper layer CL′, and compound of Ag and Cu. Herein, it needs to particularly emphasize that, the feather-like microstructures are found to cause a short circuit occurring between any two of the first sensor units 11′, any two of the first extension wires 13′, or the first sensor unit 11′ and the first extension wires 13′.

FIG. 4 also shows a diagram for describing manufacturing process flow of the first sensor units and the first extension wires. After finished all of processing steps as shown in FIG. 4, another one touch panel having SOM structure is obtained. Herein, SOM is an abbreviation of “Silver nanowires-On-Metal”. The process flow firstly executes step S la so as to form a copper layer CL′ on top surface of a transparent substrate 10′. Next, in step S2a, a plurality of first extension wires 13′ are formed on the transparent substrate 10′ after a photolithography process and an etching process are applied to the copper layer CL′ in turns, and therefore an AgNW layer SNW′ is subsequently formed on the first extension wires 13′ and the transparent substrate 10′. Eventually,

Steps S3a and S4a are executed to sequentially apply a photolithography process and an etching process to the AgNW layer SNW′, so as to form a plurality of first sensor units 11′ on the transparent substrate 10′.

It is worth noting that, inventors of the present invention find that HNO₃ would simultaneously damage copper layer CL′ by passing through the AgNW layer SNW′ during the patterning process of the AgNW layer SNW′. Thus, it is easily extrapolated that, in the case of the fact that HNO₃ are not full removed from the copper layer CL′ and the AgNW layer SNW′ after a water clean process is completed, HNO₃ remaining in the copper layer CL′ and/or the AgNW layer SNW′ would continuously damage (etch) the copper layer CL′, consequently causing the trace wires (i.e., the extension wires 13′ and 14′) to be broken.

From above descriptions, the feather-like microstructures formed between the Cu-made extension wires (13′, 14′) and the AgNW-made sensor units (11′, 12′) have been found to be a serious problem on the manufacture of the touch panel having MOS structure. On the other hand, for the fabrication of the touch panel having SOM structure, there is a room for improvement in enlarging the processing window of the Cu-made extension wires (13′, 14′) during HNO₃ being used to pattern the AgNW layer AgNW layer SNW′. In view of that, inventors of the present application have made great efforts to make inventive research and eventually provided an alloy for making trace wires and touch panel using the same.

### SUMMARY OF THE INVENTION

The primary objective of the present invention is to provide an alloy for making trace wires and touch panel using the same. The alloy mainly comprises a first clapping layer, a second clapping layer, and a copper layer disposed between the first clapping layer and the second clapping layer. By applying the alloy as the trace wires of the touch panel, feather-like microstructures are effectively prevented from forming between the trace wires and sensor units of the touch panel. On the other hand, because this novel alloy is able to completely defense the corrosion attack coming from HNO₃-based etchant, the trace wires made of the alloy exhibits an outstanding corrosion resistant during the patterning process of the AgNW-made sensor units. Therefore, during patterning the AgNW-made sensor units, the touch panel has a good manufacturing yield rate since the processing window of the trace wires is enlarged. Moreover, the end product of the touch panel using this alloy as its trace wires also possesses an outstanding reliability.

In order to achieve the primary objective of the present invention, the inventor of the present invention provides an embodiment for the alloy for making trace wires, comprising:
a first clapping layer;
a copper layer formed on the first clapping layer; and
a second clapping layer formed on the copper layer;
wherein both the first clapping layer and the second clapping layer are made of a metal material having an electrode potential lower than an electrode potential of the copper layer.

Moreover, the inventor of the present invention also provides one embodiment for the touch panel, comprising:
a transparent substrate;
a plurality of first sensor units, being made of silver nanowires (AgNWs) or copper nanowires (CuNWs), and being formed on one surface of the transparent substrate;
a plurality of first extension wires, being formed on one surface of the transparent substrate, and being respectively connected to the plurality of first sensor units;
a plurality of second sensor units, being made of the AgNWs or the CuNWs, and being formed on another one surface of the transparent substrate; and
a plurality of second extension wires, being formed on another one surface of the transparent substrate, and being respectively connected to the plurality of second sensor units;
wherein both the first extension wires and the second extension wires are made of an alloy, and the alloy comprising:
   a first clapping layer;
   a copper layer formed on the first clapping layer; and
   a second clapping layer formed on the copper layer, wherein both the first clapping layer and the second clapping layer are made of a metal material having an electrode potential lower than an electrode potential of the copper layer.

In the embodiment of the alloy and the embodiment of the touch panel, metal material is selected from the group consisting of silver (Ag), gold (Au), platinum (Pt), palladium (Pd), iridium (Ir), iron (Fe), tin (Sn), lead (Pb), tungsten (W), nickel (Ni), chromium (Cr), zinc (Zn), aluminum (Al), magnesium (Mg), and a combination of two or more of the foregoing materials.

In the embodiment of the alloy and the embodiment of the touch panel, both the first clapping layer and the second clapping layer have a thickness in a range between 1 nm and 5 μm.

In the embodiment of the alloy and the embodiment of the touch panel, the copper layer has a thickness in a range between 1 nm and 5 μm.

In the embodiment of the alloy and the embodiment of the touch panel, the copper layer and the first clapping layer have a first thickness ratio in a range between 1:5000 and 5000:1, and the copper layer and the second clapping layer have a second thickness ratio in a range from 1:5000 to 5000:1. Moreover, there is a resistance difference ratio of the surface resistance of the first clapping layer and that of the second clapping layer, and the resistance difference ratio is less than 10%. Therefore, the copper layer disposed between the first clapping layer and the second clapping layer is able to withstand the corrosion attack coming from an etchant comprising principle etching ingredient of 50% HNO₃ for at least 20 seconds.

### BRIEF DESCRIPTION OF THE DRAWINGS

The invention as well as a preferred mode of use and advantages thereof will be best understood by referring to the following detailed description of an illustrative embodiment in conjunction with the accompanying drawings, wherein:

FIG. 1 shows a top view diagram of a conventional double-sided ITO touch panel;

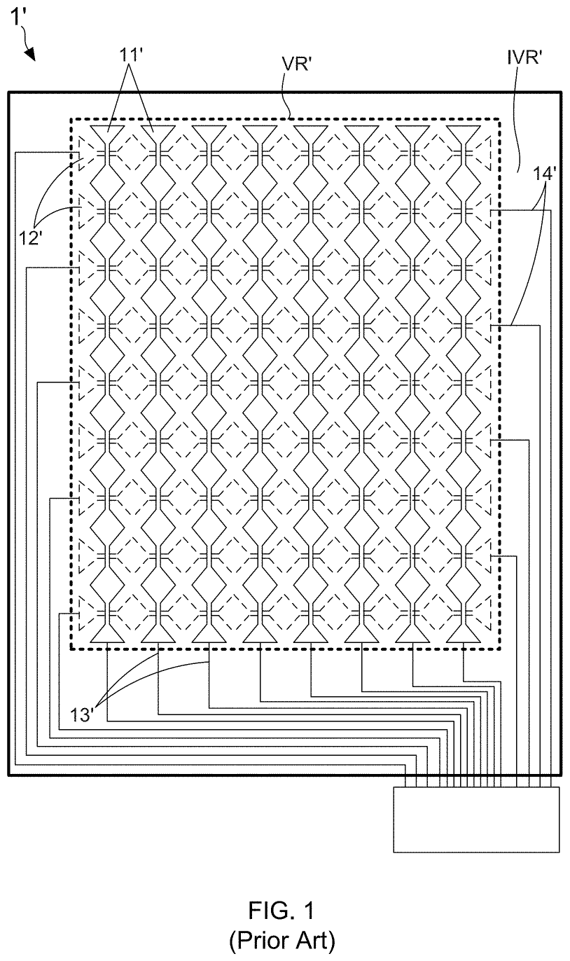

FIG. 2 shows a cross-sectional side view of the conventional double-sided ITO touch panel;

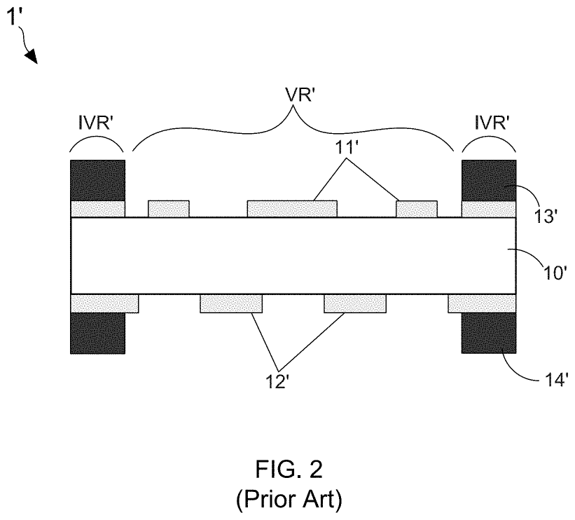

FIG. 3A and FIG. 3B show diagrams for describing manufacturing process flow of a plurality of first sensor units and a plurality of first extension wires;

FIG. 4 also shows a diagram for describing manufacturing process flow of the first sensor units and the first extension wires;

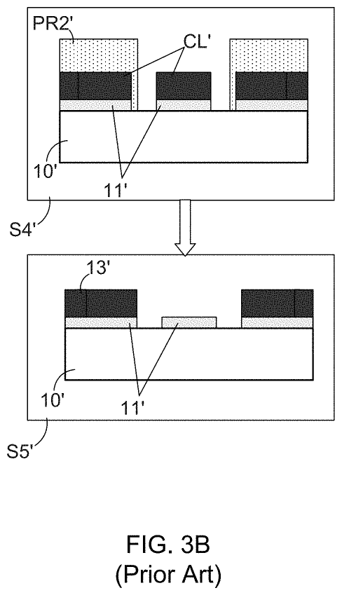

FIG. 5 shows a cross-sectional side view of an alloy for making trace wires according to the present invention;

FIG. 6 shows images for presenting microstructures of a sample 1;

FIG. 7 shows images for presenting microstructures of a sample 2;

FIG. 8 shows images for presenting microstructures of a sample 3;

FIG. 9 shows images for presenting microstructures of a sample 4; and

FIG. 10 shows a stereo exploded view of a touch panel having traces wire made of the alloy.

### DETAILED DESCRIPTION OF THE PREFERRED EMBODIMENTS

To more clearly describe an alloy for making trace wires and touch panel having traces wire made of the alloy according to the present invention, embodiments of the present invention will be described in detail with reference to the attached drawings hereinafter.

Embodiment of the Alloy for Making Trace Wires of a Touch Panel

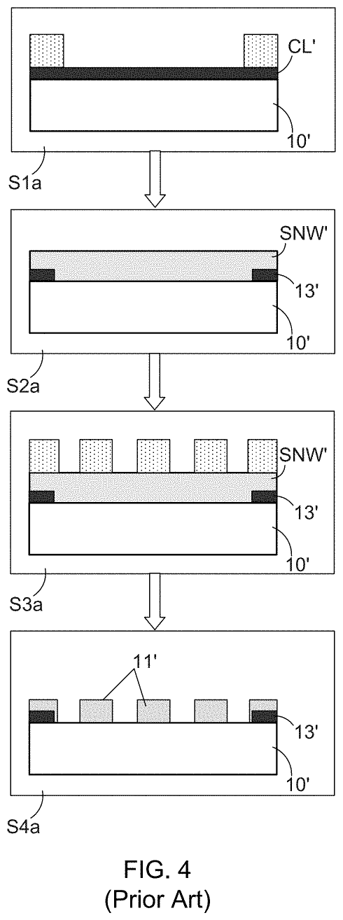

With reference to FIG. 5, there is shown a cross-sectional side view of an alloy for making trace wires according to the present invention. In the present invention, a particularly-designed alloy is proposed for making a plurality of trace wires of a touch panel, wherein the touch panel having a plurality of sensor units made of silver nanowires (AgNWs) or copper nanowires (CuNWs). Moreover, as FIG. 5 shows, the alloy 1 of the present invention comprises: a first clapping layer 11, a copper layer 12 formed on the first clapping layer 11, and a second clapping layer 13 formed on the copper layer 12.

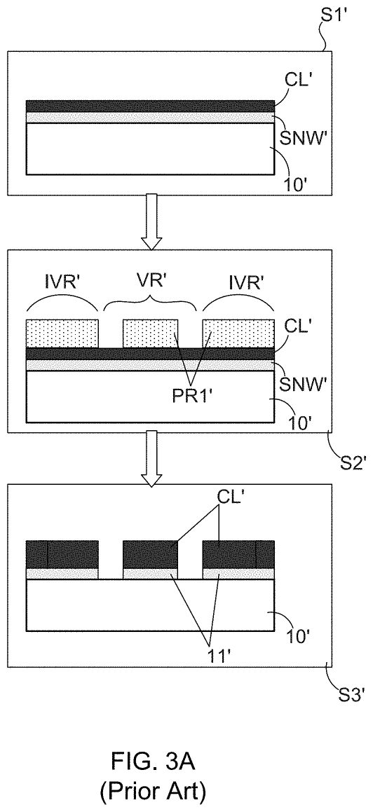

Foregoing FIG. 3A have described that, during the pattering process of the first sensor units 11′, a first etchant comprising principle etching ingredient of HNO₃ or FeCl₃ is firstly applied to the copper layer CL′, and therefore a second etchant comprising principle etching ingredient of HNO₃ is subsequently applied to the AgNW layer SNW′. However, Galvanic displacement reaction and nucleation reaction would occur between AgNO₃ and Cu element of the copper layer CL′, wherein the AgNO₃ is produced during using HNO₃ to etch the AgNW layer SNW′. Consequently, Galvanic displacement reaction and nucleation reaction cause that feather-like microstructures are formed between the copper layer CL′ and the first sensor units 11′.

For effectively preventing the production of the said feather-like microstructures, the present invention particularly adopts a metal material to make both the first clapping layer 11 and the second clapping layer 13, wherein the electrode potential of the is lower than that of the copper layer CL′. Exemplary material for making the two clapping layers 11 and 13 are summarized and listed in following Table (1).

TABLE (1)

| Half reaction | |
|---|---|
| Oxidation state [symbol] Reduction state | E⁰(V) |
| Mg⁺ + e⁻ [symbol] Mg(s) | −2.93 |
| Al(OH)₄⁻ + 3e⁻ [symbol] Al(s) + 4OH⁻ | −2.33 |
| Zn²⁺ + 2e⁻ [symbol] Zn(s) | −0.7618 |
| PbO(s) + H₂O + 2e⁺ + 2e⁻ [symbol] Pb(s) + 2OH⁻ | −0.58 |
| Fe²⁺ + 2e⁻ + 2e⁻ [symbol] Fe(s) | −0.44 |
| Cr³⁺ + e⁻ [symbol] Cr²⁺ | −0.42 |
| PbSO₄(s) + 2e⁻ [symbol] Pb(s) + SO₄²⁻ | −0.36 |
| Ni²⁺ + 2e⁻ [symbol] Ni(s) | −0.25 |
| Sn²⁺ + 2e⁻ [symbol] Sn(s) | −0.13 |
| WO₂(s) + 4H⁺ + 4e⁻ [symbol] W(s) + 2H₂O | −0.12 |
| WO₃(aq) + 6H⁺ + 6e⁻ [symbol] W(s) + 3H₂O | −0.09 |
| Cu²⁺ + 2e⁻ [symbol] Cu(s) | 0.34 |
| Ag⁺ + e⁻ [symbol] Ag(s) | 0.8 |
| Pd²⁺ + 2e⁻ [symbol] Pd(s) | 0.915 |
| Ir³⁺ + 3e⁻ [symbol] Ir(s) | 1.156 |
| Pt²⁺ + 2e⁻ [symbol] Pt(s) | 1.188 |
| Au³⁺ + 3e⁻ [symbol] Au(s) | 1.52 |
| Cu²⁺ + e⁻ [symbol] Cu+ | 1.59 |
| Ag²⁺ + e⁻ [symbol] Ag+ | 1.98 |

From above-presented Table (1), it is understood that the metal material for making the first clapping layer 11 and the second clapping layer 13 is selected from the group consisting of silver (Ag), gold (Au), platinum (Pt), palladium (Pd), iridium (Ir), iron (Fe), tin (Sn), lead (Pb), tungsten (W), nickel (Ni), chromium (Cr), zinc (Zn), aluminum (Al), magnesium (Mg), and a combination of two or more of the foregoing materials. For example, the metal material can be Ni—Cr compound, Ni—W compound, or Ni—Co compound, such that the alloy 1 of the present invention has a sandwich structure of Ni—Cr/Cu/Ni—Cr, Ni—W/Cu/Ni—W, or Ni—Co/Cu/Ni—Co, correspondingly. Of course, the manufacturing material of the first clapping layer 11 can be different from that of the second clapping layer 13. Moreover, according to the particular design of the present invention, the copper layer 12 and the first clapping layer 11 have a first thickness ratio in a range between 1:5000 and 5000:1, and the copper layer 12 and the second clapping layer 13 have a second thickness ratio in a range from 1:5000 to 5000:1. In a practical application, both the first clapping layer 11 and the second clapping layer 13 are set to have a thickness in a range between 1 nm and 5 μm, and the copper layer 12 has a thickness in a range between 1 nm and 5 μm.

Experiment I

In order to prove that the use of the first clapping layer 11 and the second clapping layer 13 is help for preventing Galvanic displacement reaction from occurring between AgNO₃ and Cu element of copper layer CL′, inventors of the present invention complete experiment I. In the experiment I, alloy 1 having sandwich structure as shown in FIG. 5 is adopted for the manufacture of trace wires formed on an AgNW layer, wherein the AgNW layer is formed on a substrate. Following Table (2) summarizes the structure descriptions of two samples made in the experiment I.

TABLE (2)

| | Sample 1 | Sample 2 |
|---|---|---|
| Structure | Second clapping layer 13 | Second clapping layer 13 |
| | Copper layer 12 | Copper layer 12 |
| | First clapping layer 11 | First clapping layer 11 |
| | AgNW layer SNW | AgNW layer SNW |

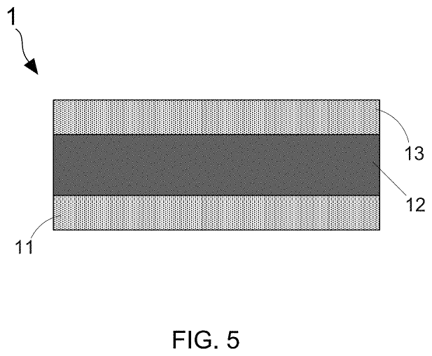

Microstructures of sample 1 are presented by two images as shown in FIG. 6. It needs to further explain that, the sample 1 is a touch panel having MOS structure, and both the first clapping layer 11 and the second clapping layer 13 are made of Cu-containing material. From image (a) of FIG. 6, it is found that, Galvanic displacement reaction and nucleation reaction occur between AgNO₃ and Cu element of the copper layer 12 during the pattering process of the AgNW layer SNW, eventually causing that feather-like microstructures F comprising principle ingredient of silver (Ag) are formed between the copper layer 12 and the sensor units (i.e., the patterned AgNW layer SNW) of the touch panel. Moreover, a zoom-in view of the feather-like microstructures F can be found in image (b) of FIG. 6. After removing the copper layer 12, it is observed that the feather-like microstructures F is formed along a three-phase interface comprising copper layer 12, etchant and AgNW layer SNW.

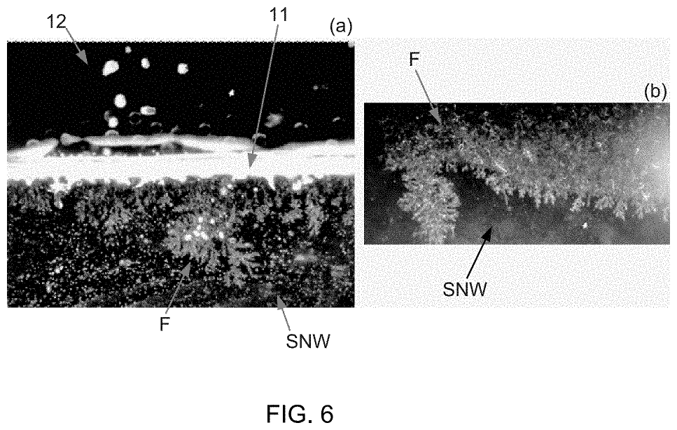

On the other hand, microstructures of sample 2 are presented by two images as shown in FIG. 7. The sample 2 is also a touch panel having MOS structure. However, differently, both the first clapping layer 11 and the second clapping layer 13 are made of Ni—Cr compound. Moreover, the thickness of the first clapping layer 11, the copper layer 12 and the second clapping layer 13 are respectively 20 nm, 250 nm and 20 nm, and the sample 2 shows a surface resistance of 0.13 ohm/sq. Particularly, from images (a) and (b) of FIG. 7, it is observed that there is no feather-like microstructures F forming along the three-phase interface comprising copper layer 12, etchant and AgNW layer SNW. Thus, experimental data have proved that the use of the first clapping layer 11 and the second clapping layer 13 indeed can prevent the formation of the feather-like microstructures F comprising principle ingredient of silver (Ag).

Experiment II

Inventors of the present invention further complete experiment II. In the experiment II, alloy 1 having sandwich structure as shown in FIG. 5 is adopted for the manufacture of trace wires formed on a substrate, and there is an AgNW layer further formed on the trace wires. Following Table (3) summarizes the structure descriptions of two samples made in the experiment II.

TABLE (3)

| | Sample 1 | Sample 2 |
|---|---|---|
| Structure | AgNW layer SNW | AgNW layer SNW |
| | Second clapping layer 13 | Second clapping layer 13 |
| | Copper layer 12 | Copper layer 12 |
| | First clapping layer 11 | First clapping layer 11 |

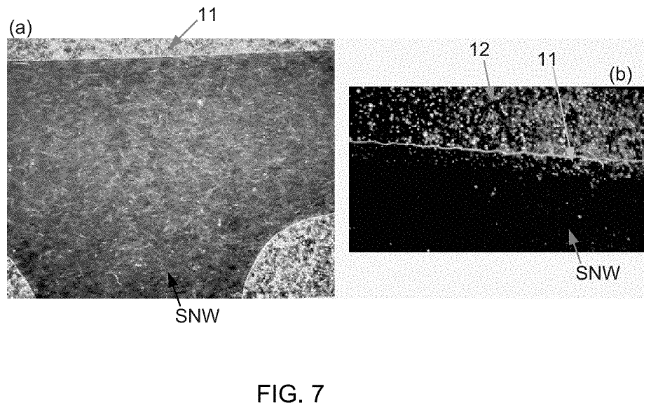

Microstructures of sample 3 are presented by the image as shown in FIG. 8. It needs to further explain that, the sample 3 is a touch panel having SOM structure, and both the first clapping layer 11 and the second clapping layer 13 are made of Cu-containing material. From image of FIG. 8, it is found that, Galvanic displacement reaction and nucleation reaction occur between AgNO₃ and Cu element of the copper layer 12 during the pattering process of the AgNW layer SNW, eventually causing that feather-like microstructures F comprising principle ingredient of silver (Ag) are formed between the copper layer 12 and the sensor units (i.e., the patterned AgNW layer SNW) of the touch panel. Moreover, related experimental result also indicate that the copper layer 12 shows poor etching resistance against to etchant of the AgNW layer SNW, causing the side edges of the copper layer 12 be irregular. It is worth noting that, in the case of the fact that the etchant comprising principle ingredient of HNO₃ are not full removed from the patterned copper layer 12 (i.e., the trace wires) and the patterned AgNW layer SNW (i.e., the sensor units), HNO₃ remaining in the copper layer 12 and/or the AgNW layer SNW would continuously damage (etch) the copper layer 12, consequently causing the trace wires (i.e., the sample 3) to be broken.

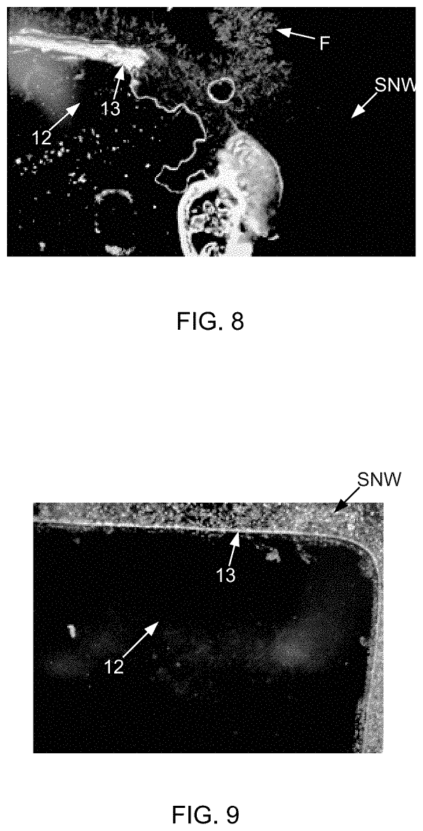

On the other hand, microstructures of sample 4 are presented by the image as shown in FIG. 9. The sample 4 is also a touch panel having SOM structure. However, differently, both the first clapping layer 11 and the second clapping layer 13 are made of Ni—Cr compound. Moreover, the thickness of the first clapping layer 11, the copper layer 12 and the second clapping layer 13 are respectively 20 nm, 250 nm and 20 nm. Particularly, from image of FIG. 9, it is observed that there is no feather-like microstructures F forming between the copper layer 12 and AgNW layer SNW. Thus, experimental data have proved that the use of the first clapping layer 11 and the second clapping layer 13 indeed can prevent the formation of the feather-like microstructures F comprising principle ingredient of silver (Ag). Moreover, related experimental data also report that, the copper layer 12 disposed between the first clapping layer 11 and the second clapping layer 13 is able to withstand the corrosion attack coming from an etchant comprising principle etching ingredient of 50% HNO₃ for at least 20 seconds. Therefore, after completing the patterning process of the AgNW layer SNW, the side edges of the copper layer 12 in patterned alloy 1 layer (i.e., the trace wires of the touch panel) is regular and sharp.

Based on the supports of experimental data, it is believable that the alloy 1 of the present invention can fully defense the corrosion attack coming from HNO₃-based etchant during the patterning process of the AgNW layer (i.e., the sensor units of the touch panel). Therefore, it is extrapolated that, the width and the pitch of the trace wires and/or the sensor units of the touch panel can be precisely controlled by etching process, in the case of the alloy 1 of the present invention being adopted for the manufacture of the trace wires. Therefore, during patterning the AgNW-made sensor units, the touch panel has a good manufacturing yield rate since the processing window of the trace wires is enlarged. Moreover, the end product of the touch panel using this alloy as its trace wires also possesses an outstanding reliability because there is no HNO₃-based etchant remaining the trace wires and/or the sensor units.

Embodiment of the Touch Panel Having Traces Wire Made of the Alloy

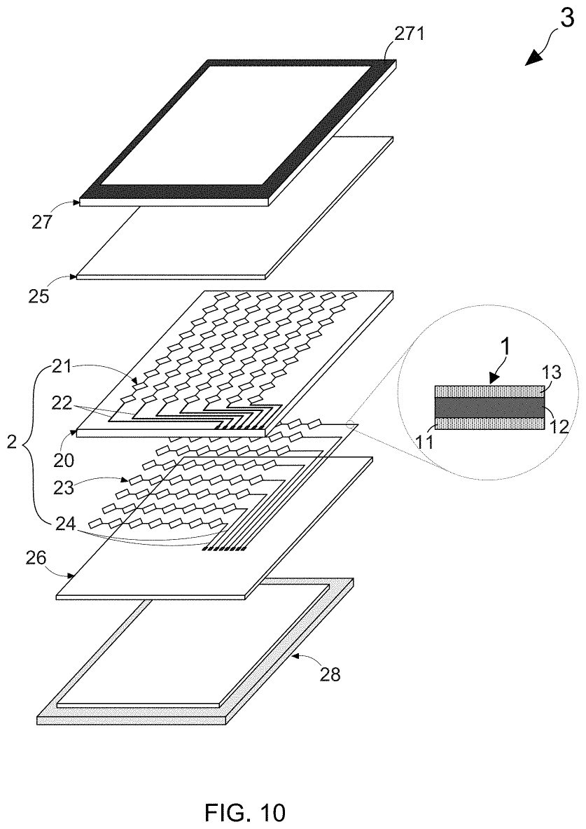

FIG. 10 shows a stereo exploded view of a touch panel having traces wire made of the alloy. The touch panel 2 mainly comprises: a transparent substrate 20, a plurality of first sensor units 21, a plurality of first extension wires 22, a plurality of second sensor units, and a plurality of second extension wires 24. In is worth noting that, the first extension wires 22 and the second extension wires 24 constitute the trace wires of the touch panel 2, and the touch panel 2 and a liquid crystal module (LCM) 28 can be further are integrated to a touch display panel 3. On the other hand, the first sensor units 21 are made of silver nanowires (AgNWs) formed on one surface of one surface of the transparent substrate 20. Moreover, the first extension wires 21 are formed on one surface of the transparent substrate 10 and respectively connected to the first sensor units 22. Opposite to the first sensor units 21, the second sensor units 23 are also made of the AgNWs, but are formed on another one surface of the transparent substrate 20. In addition, the second extension wires 24 are formed on another one surface of the transparent substrate 20 and respectively connected to the plurality of second sensor units 23.

The first extension wires 22 and the second extension wires 24 constituted the trace wires of the touch panel 2. Particularly, both the first extension wires 22 and the second extension wires 24 are made of the above-introduced alloy 1, comprising: a first clapping layer 11, a second clapping layer 13, and a copper layer 12 disposed between the first clapping layer 11 and the second clapping layer 13.

In a practical application, the touch display panel 2 may further comprises: a first optical adhesive layer 25, a second optical adhesive layer 26 and a protection glass 27. The first optical adhesive layer 25 is coated onto the transparent substrate 20, and covers the first sensor units 21 and the first extension wires 22. Moreover, the second optical adhesive layer 26 is coated onto the transparent, and covers the second sensor units 23 and the second extension wires 24. In addition, the protection glass 27 is attached onto the transparent substrate 20 via the first optical adhesive layer 25, and the LCM 28 is attached onto the transparent substrate 20 through the second optical adhesive layer 26. From FIG. 10, it is found that, there is an opaque layer 271 disposed on the protection glass 27. By such arrangement, the protection glass 27 comprises a transparent region (i.e., visible region) and an opaque region (i.e., non-visible region). Engineer skilled development and manufacture of touch panel should know that, the first sensor units 21 and the second sensor units 23 are arranged in the visible region of the touch panel 2. Moreover, the first extension wires 22 and the second extension wires 24 are arranged in the non-visible region.

Therefore, through above descriptions, the alloy for making trace wires and touch panel using the alloy have been introduced completely and clearly; in summary, the present invention includes the advantages of:

(1) The present invention provides an alloy 1 for making trace wires of a touch panel 2. The alloy 1 mainly comprises a first clapping layer 11, a second clapping layer 13, and a copper layer 12 disposed between the first clapping layer 11 and the second clapping layer 13. By applying the alloy 1 as the trace wires of the touch panel, feather-like microstructures are effectively prevented from forming between the trace wires and sensor units of the touch panel. On the other hand, because this novel alloy 1 is able to completely defense the corrosion attack coming from HNO₃-based etchant, the trace wires made of the alloy 1 exhibits an outstanding corrosion resistant during the patterning process of the AgNW-made sensor units. Therefore, during patterning the AgNW-made sensor units, the touch panel has a good manufacturing yield rate since the processing window of the trace wires is enlarged. Moreover, the end product of the touch panel using this 1 alloy as its trace wires also possesses an outstanding reliability because there is no HNO₃-based etchant remaining the trace wires and/or the sensor units.

The above description is made on embodiments of the present invention. However, the embodiments are not intended to limit scope of the present invention, and all equivalent implementations or alterations within the spirit of the present invention still fall within the scope of the present invention.

What is claimed is:

1. An alloy for making a plurality of trace wires of a touch panel, wherein the touch panel having a plurality of sensor units made of silver nanowires (AgNWs) or copper nanowires (CuNWs), and the alloy comprising:
a first clapping layer;
a copper layer formed on the first clapping layer; and
a second clapping layer formed on the copper layer;
wherein both the first clapping layer and the second clapping layer are made of a metal material having an electrode potential lower than an electrode potential of the copper layer.

2. The alloy of claim 1, wherein the metal material is selected from the group consisting of silver (Ag), gold (Au), platinum (Pt), palladium (Pd), iridium (Ir), iron (Fe), tin (Sn), lead (Pb), tungsten (W), nickel (Ni), chromium (Cr), zinc (Zn), aluminum (Al), magnesium (Mg), and a combination of two or more of the foregoing materials.

3. The alloy of claim 1, wherein both the first clapping layer and the second clapping layer have a thickness in a range between 1 nm and 5 μm.

4. The alloy of claim 1, wherein the copper layer has a thickness in a range between 1 nm and 5 μm.

5. The alloy of claim 1, wherein the copper layer and the first clapping layer have a first thickness ratio in a range between 1:5000 and 5000:1, and the copper layer and the second clapping layer having a second thickness ratio in a range from 1:5000 to 5000:1.

6. A touch panel, comprising:
a transparent substrate;
a plurality of first sensor units, being made of silver nanowires (AgNWs) or copper nanowires (CuNWs), and being formed on one surface of the transparent substrate;
a plurality of first extension wires, being formed on one surface of the transparent substrate, and being respectively connected to the plurality of first sensor units;
a plurality of second sensor units, being made of the AgNWs or the CuNWs, and being formed on another one surface of the transparent substrate; and
a plurality of second extension wires, being formed on another one surface of the transparent substrate, and being respectively connected to the plurality of second sensor units;
wherein both the first extension wires and the second extension wires are made of an alloy, and the alloy comprising:
a first clapping layer;
a copper layer formed on the first clapping layer; and
a second clapping layer formed on the copper layer, wherein both the first clapping layer and the second clapping layer are made of a metal material having an electrode potential lower than an electrode potential of the copper layer.

7. The touch panel of claim 6, wherein the touch panel and a liquid crystal module (LCM) are integrated to a touch display panel.

8. The touch panel of claim 6, wherein the metal material is selected from the group consisting of silver (Ag), gold (Au), platinum (Pt), palladium (Pd), iridium (Ir), iron (Fe), tin (Sn), lead (Pb), tungsten (W), nickel (Ni), chromium (Cr), zinc (Zn), aluminum (Al), magnesium (Mg), and a combination of two or more of the foregoing materials.

9. The touch panel of claim 6, wherein both the first clapping layer and the second clapping layer have a thickness in a range between 1 nm and 5 μm.

10. The touch panel of claim 6, wherein the copper layer has a thickness in a range between 1 nm and 5 μm.

11. The touch panel of claim 6, wherein the copper layer and the first clapping layer have a first thickness ratio in a range between 1:5000 and 5000:1, and the copper layer and the second clapping layer having a second thickness ratio in a range from 1:5000 to 5000:1.

12. The touch panel of claim 7, wherein the touch display panel further comprises:
a first optical adhesive layer, being coated onto the transparent substrate, and covering the plurality of first sensor units and the plurality of first extension wires;
a second optical adhesive layer, being coated onto the transparent substrate, and covering the plurality of second sensor units and the plurality of second extension wires; and
a protection glass, being attached onto the transparent substrate via the first optical adhesive layer, and the liquid crystal module being attached onto the transparent substrate through the second optical adhesive layer.

13. The touch panel of claim 12, wherein an opaque layer is further disposed on the protection glass, so as to make the protection glass comprise a transparent region and an opaque region on the protection glass.
